(19) United States
(12) Patent Application Publication
(10) Pub. No.: US 2010/0320570 A1
(43) Pub. Date: Dec. 23, 2010

(54) SEMICONDUCTOR DEVICE

(75) Inventors: Hideyuki Nakamura, Kanagawa (JP); Toshifumi Takahashi, Kanagawa (JP); Yuji Ikeda, Kanagawa (JP); Sumito Minagawa, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/775,115

(22) Filed: May 6, 2010

(30) Foreign Application Priority Data
Jun. 22, 2009 (JP) 2009-147484

(51) Int. Cl. H01L 29/06

(52) U.S. Cl. 257/547; 257/E29.019

(57) ABSTRACT

The present invention includes a memory cell area that includes a plurality of transistors, and a core area that is arranged adjacent to the memory cell area. The memory cell area and the core area include a semiconductor layer, and an n-type well region and a first p-type well region formed above the semiconductor layer. The memory cell area further includes a second p-type well region formed under the n-type well region and the first p-type well region in the semiconductor layer. The second p-type well region contacts to at least the first p-type well region.

### INCORPORATION BY REFERENCE

This application is based upon and claims the benefit of priority from Japanese patent application No. 2009-147484, filed on Jun. 22, 2009, the disclosure of which is incorporated herein in its entirety by reference.

### BACKGROUND

1. Field of the Invention

The present invention relates to a semiconductor device, and more particularly, to a semiconductor device that has excellent soft error tolerance.

2. Description of Related Art

For example, a SRAM (Static Random Access Memory) is used as a semiconductor device in which a memory cell is composed of CMOS (Complementary Metal Oxide Semiconductor)-type transistors. It is known that latch up and soft errors occur by background radiation in the SRAM.

For example, the structure for preventing the latch up is disclosed in Japanese Unexamined Patent Application Publication No. 2000-164819. In Japanese Unexamined Patent Application Publication No. 2000-164819, a p-type well region and an n-type well region have two layers composed of an upper layer and a lower layer. A leak current is reduced by separating the p-type well region from the n-type well region in the lower layer, thereby the latch up is prevented.

Further, Japanese Unexamined Patent Application Publication Nos. 2006-59880, 6-275796, 2005-166723, 6-310683, and 2003-218323 disclose structures that improve the soft error tolerance of semiconductor devices. In Japanese Unexamined Patent Application Publication No. 2006-59880, the structure in which a deep well is formed partly in a lower portion of a regular well region is proposed. This structure suppresses change of a depletion layer caused by incidence of radiation, thereby it is possible to improve the soft error tolerance of the semiconductor device.

In Japanese Unexamined Patent Application Publication No. 6-275796, a buried region is formed in a lower portion of a regular well region, which is separated from the regular well region. The buried region makes it possible to prevent minority careers generated by incidence of radiation from entering memory cells. Therefore, it is possible to improve the soft error tolerance of the semiconductor device.

In Japanese Unexamined Patent Application Publication No. 2005-166723, the structure in which a region having high impurity concentration and a buried layer are formed partly in a lower portion of a regular well region is proposed. This makes it possible to prevent the contact capacity from increasing by the change of impurity concentration. Further, the presence of the buried layer prevents a current generated by incidence of radiation from flowing into the circuit. Therefore, it is possible to improve the soft error tolerance of the semiconductor device.

In Japanese Unexamined Patent Application Publication No. 6-310683, well regions in a memory cell area are formed more shallowly than well regions in the peripheral area. Thus, it makes careers generated by incidence of radiation less prone to being collected in the well regions in the memory cell area. Therefore, it is possible to improve the soft error tolerance of the semiconductor device.

In Japanese Unexamined Patent Application Publication No. 2003-218323, it is described that a buried layer is formed on a semiconductor substrate, whose conducting type is different from the semiconductor substrate, and thereby the running of incident α-ray is restricted. Therefore, it is possible to improve the soft error tolerance of the semiconductor device.

The structure of the semiconductor device that is disclosed by Japanese Unexamined Patent Application Publication No. 2003-218323 will be described. FIG. 5 is a cross-sectional view schematically showing the structure of the semiconductor device disclosed by Japanese Unexamined Patent Application Publication No. 2003-218323. As shown in FIG. 5, the semiconductor device is divided into an effective memory cell area 100, a peripheral circuit area 200, and a dummy cell area 300.

A p-type well region 42 and an n-type well region 46 are formed on a silicon substrate 40 having p-type conductivity in the semiconductor device. In the effective memory cell area 100 and the dummy cell area 300, an n-type buried layer 50 is formed between the p-type well region 42 and the silicon substrate 40. Further, an element separating regions 18 is formed on the p-type well region 42 and the n-type well region 46. Furthermore, a gate layer 16 is formed on the p-type well region 42, the n-type well region 46, and the element separating regions 18.

Next, the mechanism that causes the soft errors will be described. In general, in consideration of the soft errors in CMOS transistors integrated device, a node kept at high level of an NMOS (N-channel Metal-Oxide-Semiconductor) transistor is effected more easily by background radiation. This is because the electron mobility is high and the ability to keep a PMOS (P-channel Metal-Oxide-Semiconductor) at high level is poor. FIGS. 6A to 6C are cross-sectional views schematically showing the NMOS transistor that formed in the p-type well region 42. As shown in FIG. 6A, the n-type buried layer 50 and the p-type well region 42 are formed in this order on the silicon substrate 40.

The gate layer 16 is formed on the p-type well region 42 with a gate insulating film 63 interposed therebetween. A source electrode 61 connected to a ground level voltage GND and a drain electrode 62 connected to a high level voltage HIGH are formed in a top portion of the p-type well region 42. Further, the element separating regions 18 are formed in the p-type well region 42 for separating transistors from adjacent transistors.

Consideration is given to the case where this NMOS transistor is irradiated with α-ray from above, for example. In this case, as shown in FIG. 6A, electrons and holes are generated along the irradiation tracks of α-ray.

Further, as shown in FIG. 6B, a part of generated electrons flows into the n-type buried layer 50. Thus, electrons flowing into the node kept at high level voltage HIGH decrease. Therefore, the soft error tolerance improves generally in the semiconductor device in which the n-type buried layer is formed.

### SUMMARY

However, the present inventors have found that it is impossible to improve the soft error tolerance of a semiconductor device that has a microstructure of a 65 nm node or finer structure, by forming the n-type buried layer on the p-type silicon substrate as disclosed in Japanese Unexamined Patent Application Publication No. 2003-218323. Further, the present inventors have found that there are cases where the soft error tolerance deteriorates on the contrary. The mechanism for this will be described below.

As shown in FIG. 6C, in such a semiconductor device, remaining holes after electrons flow out are confined in the p-type well region 42.

Further, this NMOS transistor has the microstructures of the 65 nm node or finer structure, and therefore the channel length is short. Thus, an influence of parasitic bipolar effect between a source and a drain is large. Therefore, holes confined in the p-type well region 42 amplify the parasitic bipolar effect between the source and the drain.

Thus, electrons flow from the source into a node kept at high level voltage HIGH via the drain. Therefore, it is believed that the soft error tolerance deteriorates.

Furthermore, separating the p-type well region from the n-type well region, as disclosed in Japanese Unexamined Patent Application Publication No. 2000-164819, is difficult in the semiconductor device using CMOS transistors having the microstructure of the 65 nm node or finer structure. Further, manufacturing structures disclosed in Japanese Unexamined Patent Application Publication Nos. 2006-59880, 6-275796, 2005-166723, and 6-310683 require a precise positioning process. Further, well regions that have different depth are formed in the structure disclosed in Japanese Unexamined Patent Application Publication No. 6-310683. Thus, it is necessary to add processes for each depth of well regions. Therefore, the manufacturing processes for each of those structures are complicated. As a result, manufacturing cost increases.

Therefore, it is difficult to improve the soft error tolerance of semiconductor devices having the microstructure of the 65 nm node or finer structure by applying those structures from a viewpoint of technology and manufacturing cost.

A first exemplary aspect of the present invention is a semiconductor device including a memory cell area including a plurality of transistors, and a core area arranged adjacent to the memory cell area, the memory cell area and the core area including a semiconductor layer, and an n-type well region and a first p-type well region formed above the semiconductor layer, the memory cell area, further including a second p-type well region formed under the n-type well region and the first p-type well region in the semiconductor substrate, wherein the second p-type well region contacts at least the first p-type well region.

According to the semiconductor device in accordance with an exemplary aspect of the present invention, the first p-type well regions, which are formed in the memory cell area and in which a NMOS transistor is formed, are connected with each other by the second p-type well region. Thus, a voltage change by incidence of background radiation is relaxed, thereby it is possible to prevent latch up. Further, the relaxation of confinement of generated holes suppresses an amplification of a parasitic bipolar effect between source and drain of the NMOS transistor, thereby it is possible to improve soft error tolerance.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a cross sectional view schematically showing a structure of a semiconductor device according to the first exemplary embodiment;

FIG. 2A is a cross sectional view showing a manufacturing process of the semiconductor device according to the first exemplary embodiment;

FIG. 2B is a cross sectional view showing a manufacturing process of the semiconductor device according to the first exemplary embodiment;

FIG. 2C is a cross sectional view showing a manufacturing process of the semiconductor device according to the first exemplary embodiment;

FIG. 3A is a cross sectional view schematically showing a configuration of an NMOS transistor formed in the memory cell area of the semiconductor device according to the first exemplary embodiment;

FIG. 3B is a cross sectional view schematically showing a configuration of an NMOS transistor formed in the memory cell area of the semiconductor device according to the first exemplary embodiment;

FIG. 4 is a cross sectional view schematically showing a structure of a semiconductor device according to the second exemplary embodiment;

FIG. 5 is a cross sectional view schematically showing a structure of a semiconductor device disclosed in Japanese Unexamined Patent Application Publication No. 2003-218323;

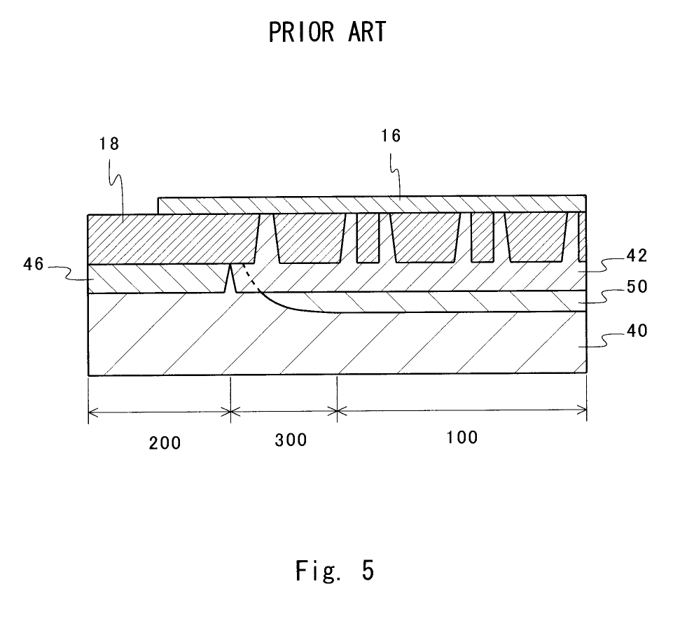

FIG. 6A is a cross sectional view schematically showing a configuration of an NMOS transistor in the semiconductor device disclosed in Japanese Unexamined Patent Application Publication No. 2003-218323;

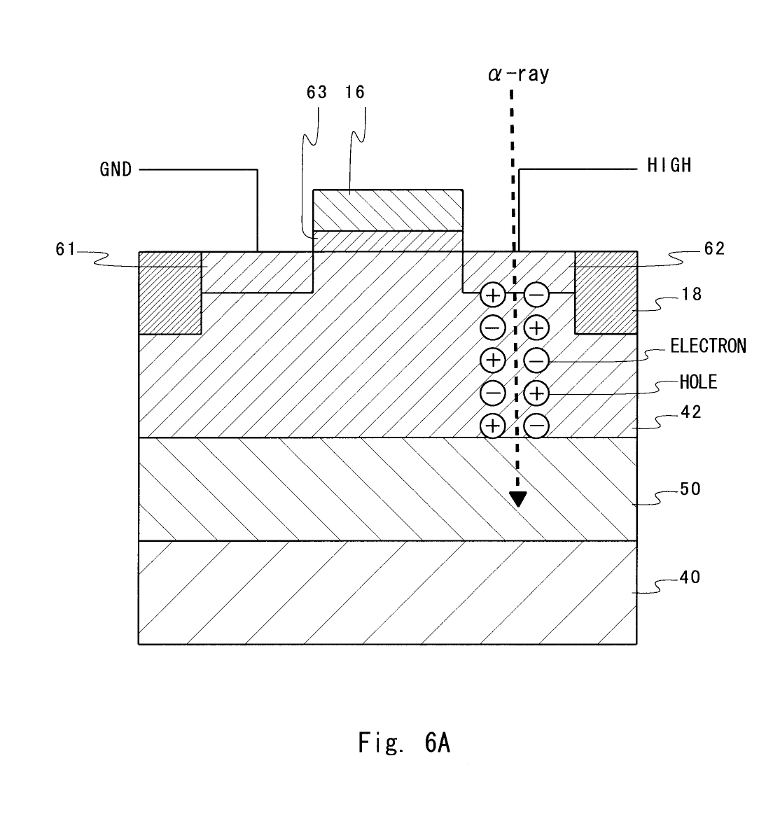

FIG. 6B is a cross sectional view schematically showing a configuration of an NMOS transistor in the semiconductor device disclosed in Japanese Unexamined Patent Application Publication No. 2003-218323; and

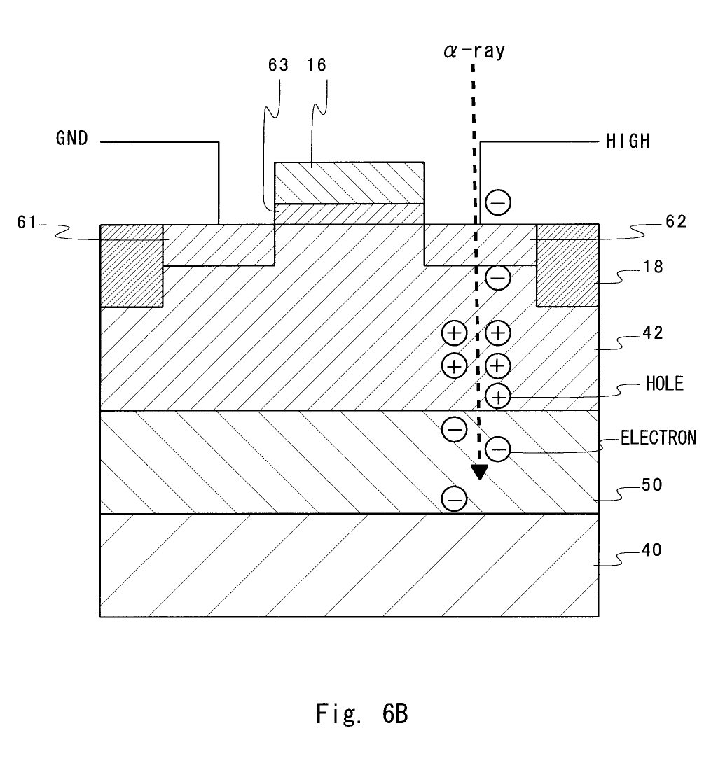

FIG. 6C is a cross sectional view schematically showing a configuration of an NMOS transistor in the semiconductor device disclosed in Japanese Unexamined Patent Application Publication No. 2003-218323.

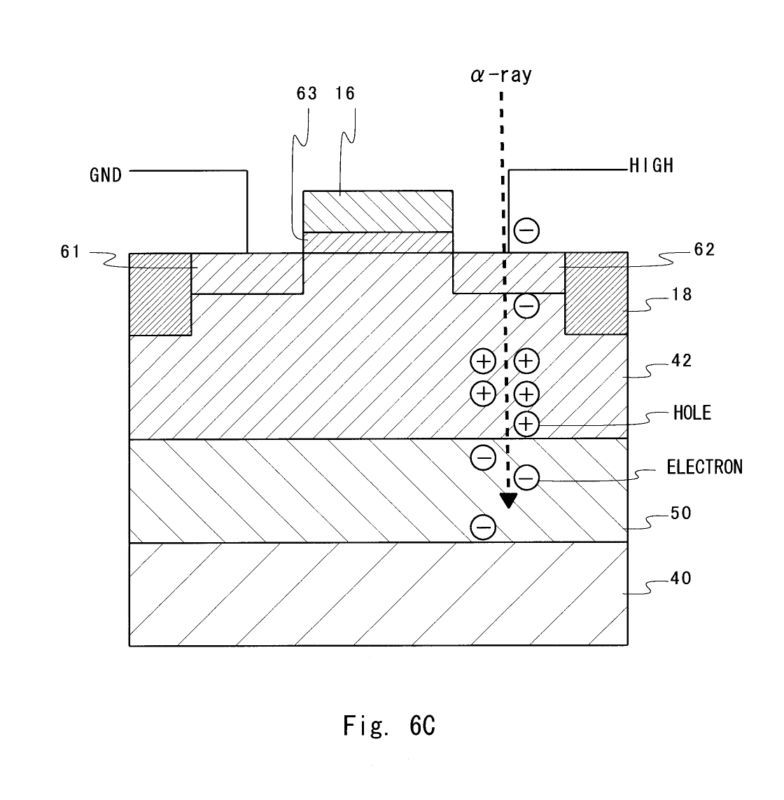

### DETAILED DESCRIPTION OF THE EMPLARY EMBODIMENTS

Hereinafter, the exemplary embodiments of the present invention will be described with reference to the drawings.

### First Exemplary Embodiment

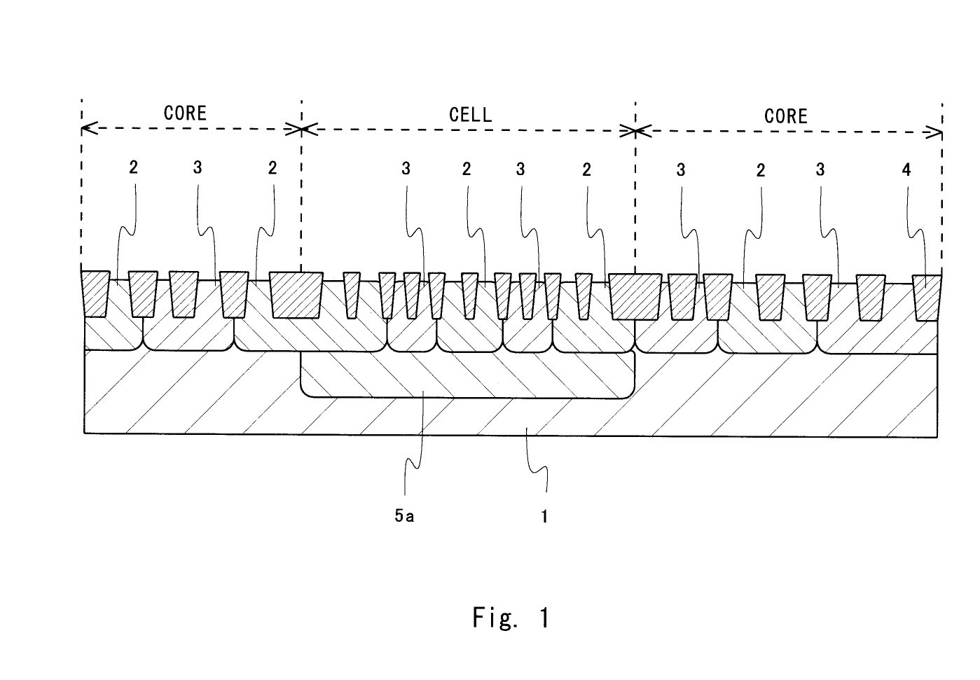

First, a semiconductor device according to a first exemplary embodiment will be described. FIG. 1 is a cross sectional view schematically showing a structure of the semiconductor device according to a first exemplary embodiment. For example, as shown in FIG. 1, p-type well regions 2 and n-type well regions 3 made of silicon are formed alternately on a substrate 1 made of silicon in the semiconductor device. Element separations 4 for separating elements from each other are formed in the p-type well region 2 and the n-type well region 3. Although not shown in drawings, electrodes and the like are formed on the p-type well region 2 divided by the element separations 4, and N-channel transistors are thereby formed. Furthermore, P-channel transistors are formed on the n-type well regions 3.

Further, this semiconductor device is divided into a memory cell area CELL and a core area CORE. In the memory cell area, memory cells composed of high density integrated CMOS transistors are arranged, for example. Further, in the core area, logic circuits and analog core regions of SoC (System-on-a-chip) are arranged, for example.

In the memory cell area CELL, a p-type deep well region 5a , which is contact with the p-type well regions 2, is formed underlying the p-type well regions 2 and the n-type well regions 3, and on the substrate 1.

Further, in FIG. 1, the n-type well regions 3 contact the p-type deep well region 5a. However, it is possible to adopt a structure in which the n-type well regions 3 do not contact the p-type deep well region 5a.

Further, the electric resistance of the p-type deep well region 5a is smaller than that of the substrate 1.

Now, the depth of the p-type deep well region 5a is defined as the distance from the surface of the p-type well regions 2 and the n-type well regions 3 to the upper surface of the p-type deep well region 5a. For example, the depth of the p-type deep well region 5a is 1.0 μm in this exemplary embodiment. Further, it is desirable that the p-type deep well region 5a is formed with such a depth that the characteristics of the transistor manufactured by using the p-type well regions 2 and the n-type well regions 3 do not deteriorate.

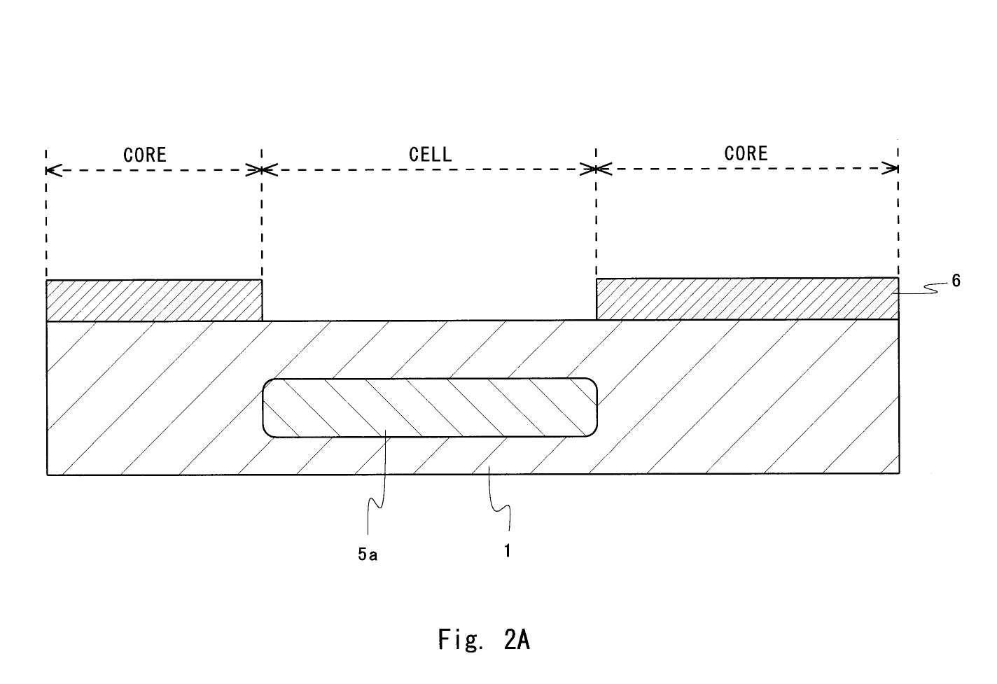

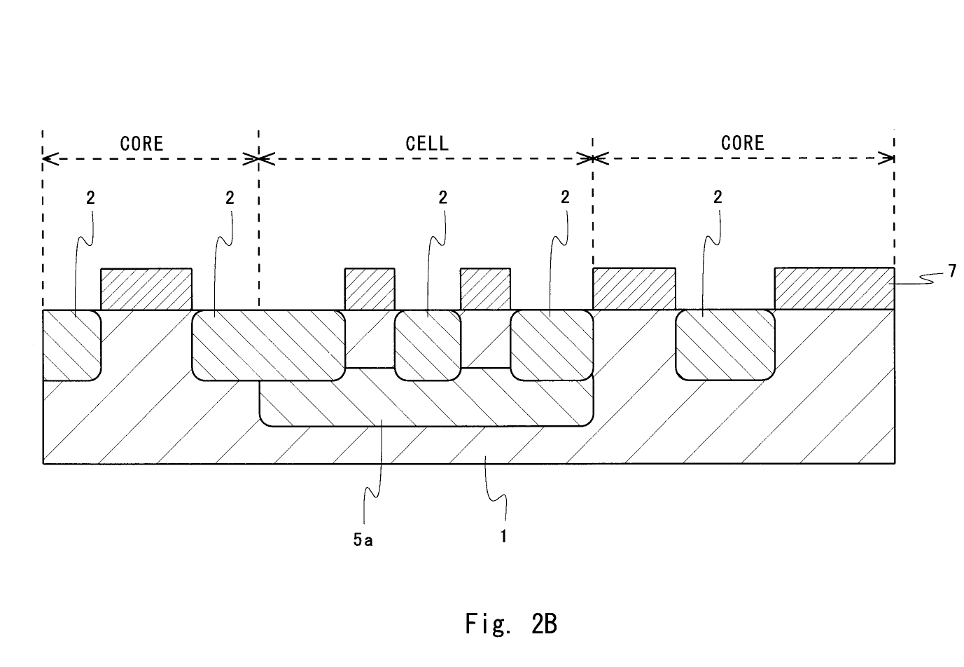

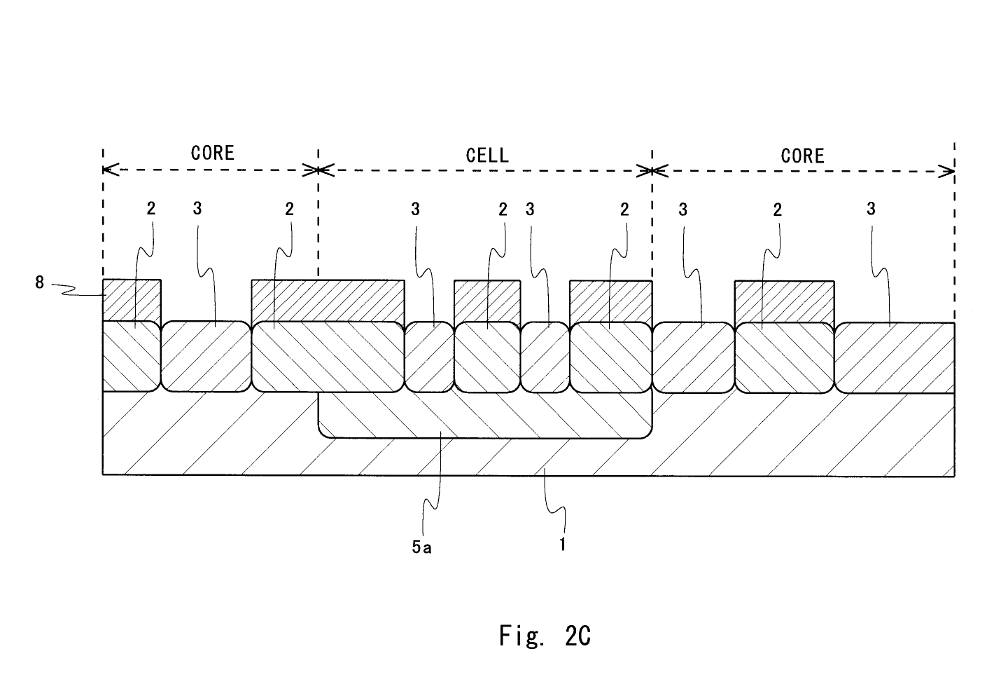

Next, a manufacturing method of this semiconductor device will be described. FIGS. 2A to 2C are cross sectional views showing the manufacturing processes of this semiconductor device. First, as shown in FIG. 2A, a resist 6 is formed on the substrate 1 by photolithography. The resist 6 has an opening in the memory cell area CELL, and covers the core area CORE. For example, by implanting boron ions using the resist 6 as a mask, the p-type deep well region 5a is formed with a predetermined depth from the principal surface of the substrate 1. Thereafter, the resist 6 is removed.

Next, as shown in FIG. 2B, a resist 7 is formed on the substrate 1 by photolithography. Subsequently, for example, by implanting boron ions using the resist 7 as a mask, the p-type well regions 2 are formed. Thereafter, the resist 7 is removed.

Next, as shown in FIG. 2C, a resist 8 is formed on the p-type well regions 2 by photolithography. Subsequently, for example, by implanting phosphorus ions using the resist 8 as a mask, the n-type well regions 3 are formed. Thereafter, the resist 8 is removed.

Next, for example, element separations 4 made of dielectric material are formed, and the semiconductor device shown in FIG. 1 is thereby manufactured. Although not shown in drawings, thereafter electrodes and the like are formed on the p-type well regions 2 and the n-type well regions 3, and the structures of transistors are thereby formed.

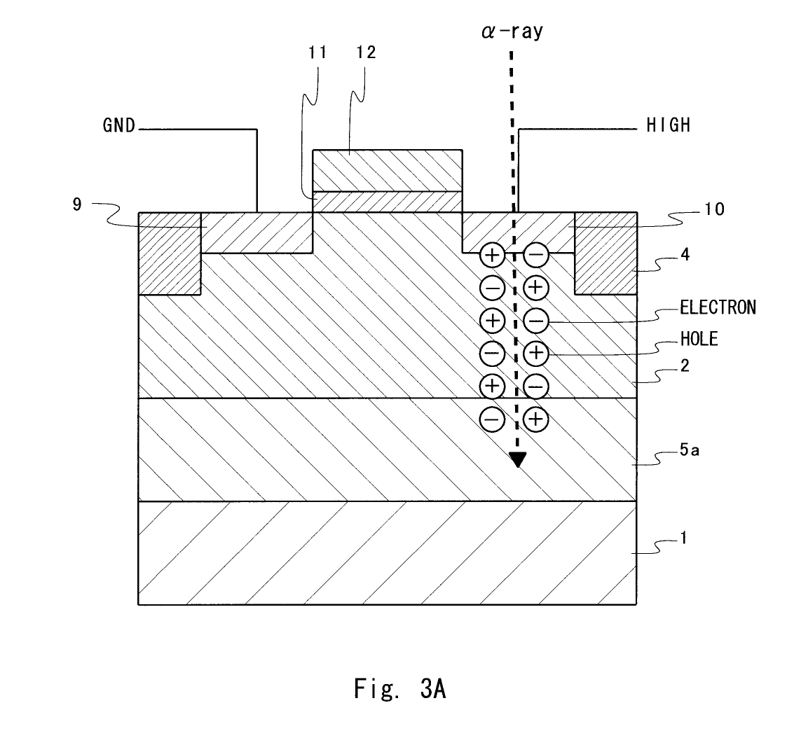

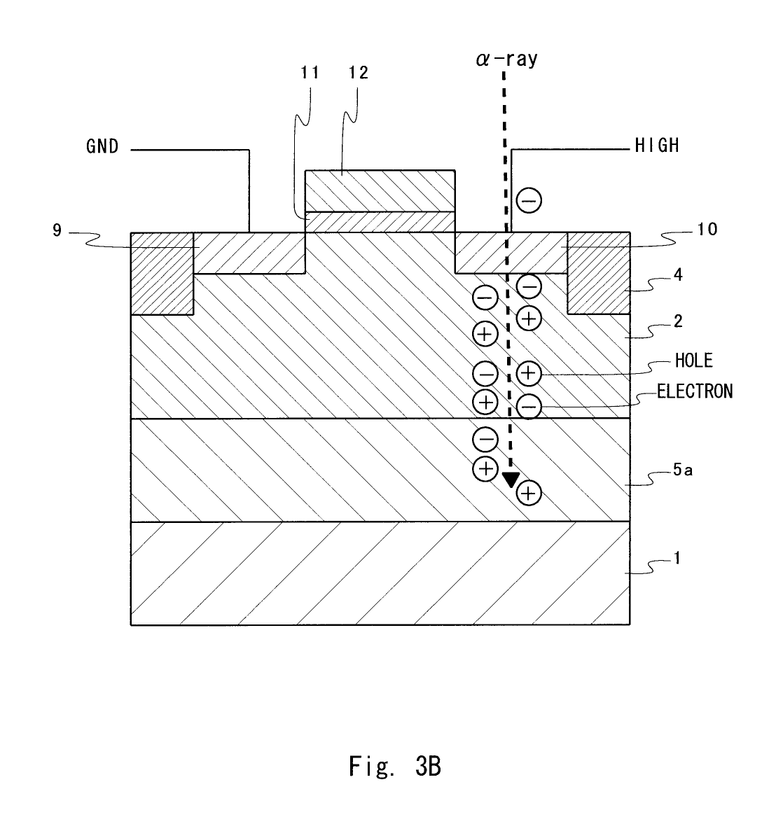

Next, the soft error tolerance in this semiconductor device will be described. FIGS. 3A and 3B are cross sectional views schematically showing the structure of the NMOS transistor formed in the memory cell area CELL of this semiconductor device. As shown in FIG. 3A, the p-type deep well region 5a and the p-type well region 2 are formed on the substrate 1 in this order in this NMOS transistor.

The gate electrode 12 is formed on the p-type well region 2 with a gate insulating film 11 interposed therebetween. A source electrode 9 connected to the ground level voltage GND and a drain electrode 10 connected to the high level voltage HIGH are formed in the upper portion of the p-type well region 2. Further, the source electrode 9 and the drain electrode 10, which have n+-type conductivity, are formed by implanting phosphorus ions, for example. Further, the element separations 4 are formed in a part of the p-type well region 2 for separating transistors from adjacent transistors.

Further, this NMOS transistor has the microstructure of the 65 nm node or finer structure, and therefore the channel length is short. Thus, an influence of parasitic bipolar effect between a source and a drain is large. As shown in FIG. 3A, for example, this NMOS transistor is irradiated with α-ray from above, and electrons and holes are generated along the irradiation tracks of α-ray.

However, the p-type deep well region 5a is formed in this NMOS transistor. Therefore, the generated holes are dispersed over the p-type well region 2 and the p-type deep well region 5a. As a result, the amplification of the bipolar effect, which would be otherwise caused by the parasitic bipolar transistor, can be suppressed. Thus, electrons that flow from the source into the drain decrease, and it is thereby possible to improve the soft error tolerance. In other words, this structure is applied to the semiconductor device having a structure of the microstructure of the 65 nm node or finer structure, and by doing so, it is possible to improve the soft error tolerance. This is one of the remarkable effects of the present invention, which is impossible to achieve by forming an n-type deep well region or an n-type buried layer as shown in the related art.

Further, the p-type deep well region 5a is formed so as to be connected to a plurality of p-type well regions 2. Therefore, although voltage change is caused by incidence of radiation, this voltage change is reduced through the p-type deep well region 5a. As a result, it is possible to prevent the latch up and the soft errors.

In additional, the electric resistance of the p-type deep well region 5a is smaller than that of the substrate 1. This makes possible to efficiently disperse electric charges generated by incidence of background radiation. Therefore, it is possible to improve the soft error tolerance.

Further, the electric resistance of the substrate 1 is larger than that of the p-type deep well region 5a, and the noise generated in the core area CORE is thereby stopped in the substrate 1. Thus, it is possible to suppress the propagation of the noise generated in the core area CORE to other circuit areas in the core area CORE and the memory cell area CELL. Therefore, by using this structure, it is possible to obtain the semiconductor device that can suppress the substrate noise excellently, especially compared to the case of using low resistant substrate.

Therefore, it is desirable to form the p-type deep well region 5a that covers the memory cell area CELL, from a view point of suppression of the latch up and the soft errors.

Further, by the manufacturing method described above, it is possible to manufacture this semiconductor device just by adding only a process of forming the p-type deep well region 5a. Further, the p-type deep well region 5a is formed so as to be connected to a plurality of the p-type well regions 2 in the memory cell area CELL, and the p-type deep well region 5a thereby has a large area. Thus, it is possible to relax the precision of position alignment and measurement control required when the resist 6 used as a mask at ion implantation is formed. Therefore, it is possible to apply low-priced process technology and manufacturing apparatuses, and it is efficient for cost reduction.

### Second Exemplary Embodiment

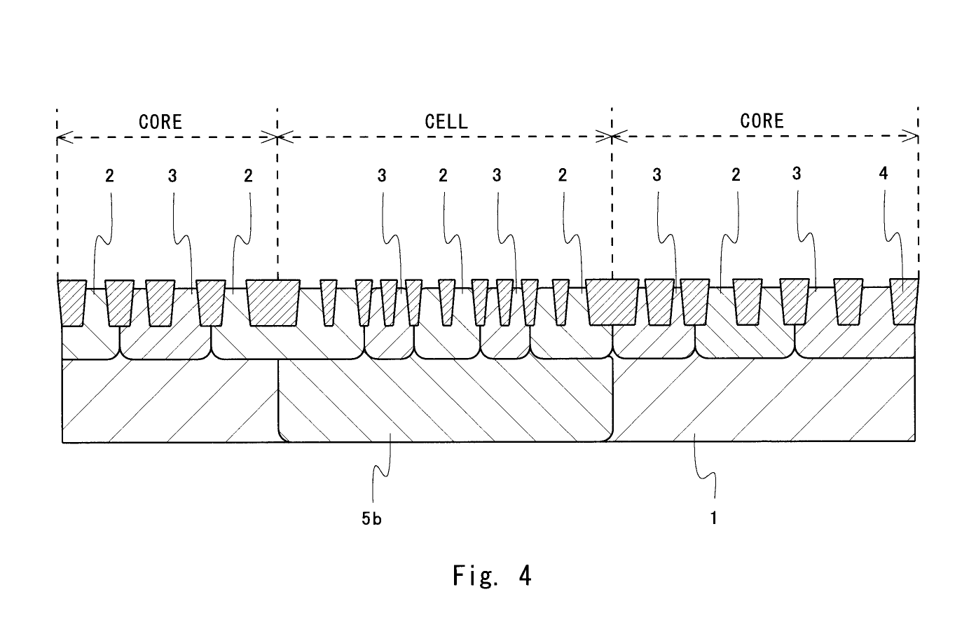

A semiconductor device according to the present exemplary embodiment is changed from the semiconductor device shown in FIG. 1 in the location where the p-type deep well region is formed. FIG. 4 is a cross sectional view schematically showing a structure of the semiconductor device according to the present exemplary embodiment. As shown in FIG. 4, the p-type deep well region 5b is formed to the bottom surface of the substrate 1 in this semiconductor device. Although not shown in drawings, the substrate 1 may be a semiconductor layer formed on another substrate. Other structures are similar to those of FIG. 1, and thus description will be omitted.

A method of manufacturing this semiconductor device will be described. In this semiconductor device, the region of the substrate 1 and the p-type deep well region 5b are formed through different manufacturing processes, by epitaxial growth, for example. Other manufacturing processes are similar to those of the first exemplary embodiment, and thus description will be omitted.

Further, after the processes in accordance with the above-mentioned manufacturing process are carried out, thinning may be performed from the bottom surface of the substrate 1 until the p-type deep well region 5b is exposed.

In the semiconductor device according to the present exemplary embodiment, it is possible to form the p-type deep well region 5b deeper than by that formed by the ion implantation. Thus, it is possible to decrease sheet resistance, and the voltage change of the p-type well region 2 by incidence of radiation is thereby reduced more efficiently. Therefore, according to this structure, it is possible to improve the soft error tolerance even further.

Note that the present invention is not limited to the above-described exemplary embodiments but can be changed as appropriate without departing from the spirit of the present invention. For example, impurity implanted to the p-type well region is not limited to phosphorus, but includes other impurities such as arsenic, for example.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. a semiconductor device comprising:
a memory cell area including a plurality of transistors; and
a core area arranged adjacent to the memory cell area,
the memory cell area and the core area comprising:
a semiconductor layer; and
an n-type well region and a first p-type well region formed above the semiconductor substrate,
the memory cell area, further comprising:
a second p-type well region formed under the n-type well region and the first p-type well region in the semiconductor layer,
wherein the second p-type well region contacts at least the first p-type well region.

2. The semiconductor device according to claim 1, wherein the second p-type well region is formed penetrating the semiconductor layer.

3. The semiconductor device according to claim 1, wherein the second p-type well region has smaller electric resistance than the semiconductor substrate.

4. The semiconductor device according to claim 1, wherein the semiconductor substrate has p-type conductivity.

5. The semiconductor device according to claim 1, wherein the second p-type well region contacts the n-type well region.

6. The semiconductor device according to claim 1, wherein the semiconductor substrate is made of silicon.
